(19) United States
(12) Patent Application Publication
(10) Pub. No.: US 2025/0343516 A1
(43) Pub. Date: Nov. 6, 2025

(54) A HIGH-SPEED, LOW-POWER, AND AREA-EFFICIENT TRANSMITTER

(71) Applicant: Rambus Inc., San Jose, CA (US)

(72) Inventors: Jinzhong Peng, Chapel Hill, NC (US); Hsuan-Jung Su, Chapel Hill, NC (US); Thoai Thai Le, Cary, NC (US)

(21) Appl. No.: 18/871,554

(22) PCT Filed: Jun. 20, 2023
(86) PCT No.: PCT/US2023/068713

§ 371 Date: Dec. 4, 2024

Related U.S. Application Data
(60) Provisional application No. 63/354,557, filed on Jun. 22, 2022.

(51) Int. Cl. H03F 3/16

(52) U.S. Cl. CPC H03F 3/16

(57) ABSTRACT

A transmitter employs simple inverters to predrive cascode-connected pull-up and pull-down output stages. Each output stage includes a drive transistor with a thin gate dielectric for fast switching. The drive transistor is cascode connected to a set of parallel-connected transistors. Calibration circuitry selectively enables the parallel-connected transistors to calibrate output resistance. The parallel transistors converge at a single resistor.

### FIELD OF THE INVENTION

The present invention relates generally to the field of communications, and more particularly to high-speed electronic signaling within and between integrated circuits.

### BACKGROUND

Electrical conductors, even very good ones, oppose the flow of electrical current and therefore the communication of electrical signals. This opposition, termed “impedance,” has two components, resistance and reactance. This disclosure focuses on resistance for ease of illustration and not by way of limitation.

A transmitter tasked with driving a signal over a conductor to a recipient device (the load) exhibits an output resistance that should be matched to the load. This matching maximizes the efficiency with which signals are propagated and minimizes signal reflections that can interfere with reception and becomes more critical with increased speed performance. High-speed transmitters therefore include circuitry for calibrating output resistance.

### BRIEF DESCRIPTION OF THE DRAWINGS

FIG. 1 illustrates, by way of example and not limitation, an integrated-circuit device with an area-efficient transmitter that supports high-speed, low-power data transmission.

### DETAILED DESCRIPTION

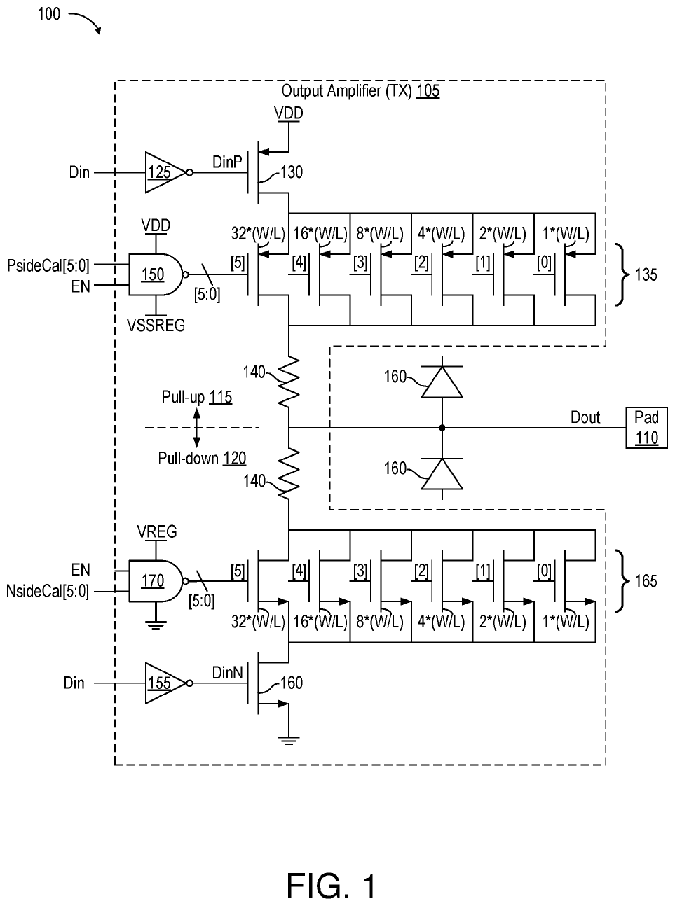

FIG. 1 depicts an integrated circuit (IC) device 100 with an area-efficient output amplifier 105, a transmitter, that supports output-resistance calibration and high-speed, low-power data transmission. Simple predrivers and drive transistors switch rapidly. Calibration circuitry for output resistance does not switch for data transmission, which relaxes design constraints and saves power. Parallel branches selectively enabled for resistance calibration converge at a single polysilicon resistor.

Amplifier 105 receives input data as common signal Din and issues amplified, singled-ended output data Dout on an output pad 110, a signal node that provides an external electrical connection to IC 100. IC 100 can be e.g. a memory device and amplifier 105 a transmitter for conveying write data to the memory device. In one embodiment, IC 100 is a Double Data Rate 5, Synchronous Dynamic Random-Access Memory (DDR5 SDRAM) and amplifier 105 supports a data rate of at least 6.4 Gbps.

Output signal Dout transitions between relatively high and low voltages to express patterns of data. Amplifier 105 is complementary. which is to say it includes two circuits 115 and 120 that mirror one another to “pull” the output voltage high and low, respectively. Beginning with pull-up circuit 115, an inverting amplifier, or “inverter,” 125 serves as a predriver that amplifies and inverts signal Din on a like-identified input node to convey data signal DinP on a like-identified output node. The term “predriver” refers to an early gain stage, gain referring to amplification, that in this example feeds a second gain stage termed a “driver,” or “output driver,” that drives the data signal to pad 110 and away from device 100.

The second gain stage includes a first drive transistor 130 cascode connected to a set of parallel second drive transistors 135. Transistor 130 has a control terminal (a gate) coupled to the output of predriver 125, a first current-handling terminal (source) coupled to a power-supply node VDD, and a second current-handling terminal (drain) cascode-connected to the uppermost current-handling terminals of second drive transistors 135, parallel calibration branches that can be independently enabled or disabled to adjust their collective resistance. In other embodiments, transistors 135 and be replaced or supplemented by a transistor calibrated via a controlled gate voltage.

A passive resistive element 140, a polysilicon resistor in this example, connects the lowermost current-handling terminals of second drive transistors 135 to output node Dout. The output resistance of pull-up circuit 115 is a function of the resistance through resistor 140 and the parallel connection of second drive transistors 135. The value of element 140 is approximate because resistance is a function of device geometry and dopant concentrations, both of which are difficult to precisely control. The resistance through transistors 135 is likewise subject to process variations that are difficult to control but their collective resistance is also a function of the combination of transistors that are enabled. Calibration logic 150 coupled to the control terminals of transistors 135 can disable one or more transistors 135 to calibrate their combined resistance. and thus the overall output resistance of pull-up circuit 115.

Each transistor 135 is labeled with a multiple of a ratio W/L, the ratio referring to the minimum width and length. The resistance of each transistor 135 is a function of its width, wider providing lower resistance. The gate widths are binary weighted so that sets of enabled transistors 135 evenly span a range of values appropriate for achieving desired calibrated resistance (e.g. 240 Ohms) given expected variations in e.g. device features, supply voltage, and temperature. Calibration logic 150 performs NAND functions of an enable signal EN and each of six calibration values PsideCal [5:0] to enable any subset of transistors 135. Disabled transistors present a high resistance to node Dout, effectively removing them from circuit 115. Enable signal EN can be de-asserted (brought low) to disable amplifier 105 altogether.

Transistors 130 and 135 are PMOS, active devices with control terminals electrically isolated from their current-handling terminals by gate dielectrics. The gate dielectric of transistor 130 can have the same or different thickness than the gate dielectrics of transistors 135. The thinner gate dielectric improves switching speed and therefore the speed performance of amplifier 105. In pull-up circuit 115, only inverter 125 and transistor 130 switch during data transmission. Transistors 135, calibration logic 150, and resistor 140 are static post calibration and are therefore less constrained. Transistors 135, when enabled, are biased to operate in a linear region during data transmission by having calibration logic 150 apply a gate voltage VSSREG, where VSSREG=VDD−VREG, selected for this purpose.

Pull-down circuit 120 is functionally similar to pull-up circuitry 115 but includes NMOS transistors 160 and 165 to pull the voltage on output node Dout toward the lower supply voltage, ground potential in this example. The gate dielectric of transistor 160 can be thin relative to those of transistors 165. An inverter 155 serves as a predriver that amplifies and inverts signal Din to convey signal PinN to transistors 160. Calibration logic 170 performs NAND functions of enable signal EN and each of calibration values NsideCal [5:0] to enable any subset of transistors 165. Transistors 165, when enabled, are biased to operate in a linear region during data transmission by having calibration logic 170 apply a gate voltage VREG. Bias voltages VREG and VSSREG can be provided by a supply external to IC 100 or can be derived internally from available supply voltages (e.g., VDD and ground).

Amplifier 105 advantageously employs simple predrivers 125 and 155 for improved power and speed performance. Calibration logic 150 and 170 do not switch for data transmission. which relaxes design constraints and saves power. The pull-up and pull-down current paths each converge at a single resistor 140, which minimizes area that would otherwise be required had each branch required a corresponding resistor.

In the foregoing description and in the accompanying drawings, specific terminology and drawing symbols arc set forth to provide a thorough understanding of the present invention. In some instances, the terminology and symbols may imply specific details that are not required to practice the invention. For example, the interconnection between circuit elements or circuit blocks may be shown or described as multi-conductor or single conductor signal lines. Each of the multi-conductor signal lines may alternatively be single-conductor signal lines, and each of the single-conductor signal lines may alternatively be multi-conductor signal lines. Signals and signaling paths shown or described as being single-ended may also be differential, and vice-versa. Similarly, signals described or depicted as having active-high or active-low logic levels may have opposite logic levels in alternative embodiments. As another example, circuits described or depicted as including metal oxide semiconductor (MOS) transistors may alternatively be implemented using bipolar technology or any other technology in which a signal-controlled current flow may be achieved. With respect to terminology, a signal is said to be “asserted” when the signal is driven to a low or high logic state (or charged to a high logic state or discharged to a low logic state) to indicate a particular condition. Conversely, a signal is said to be “de-asserted” to indicate that the signal is charged or discharged to a state other than the asserted state (including a high or low logic state, or the floating state that may occur when the signal driving circuit is transitioned to a high impedance condition, such as an open drain or open collector condition).

The output of the design process for an integrated circuit may include a computer-readable medium, such as, for example, a magnetic tape, encoded with data structures defining the circuitry can be physically instantiated as in integrated circuit. These data structures are commonly written in Caltech Intermediate Format (CIF) or GDSII, a proprietary binary format. Those of skill in the art of mask preparation can develop such data structures from schematic diagrams of the type detailed above.

While the invention has been described with reference to specific embodiments thereof, it will be evident that various modifications and changes may be made thereto without departing from the broader spirit and scope of the invention. Variations of these embodiments will be apparent to those of ordinary skill in the art upon reviewing this disclosure. Moreover, some components are shown directly connected to one another while others are shown connected via intermediate components. In each instance the method of interconnection, or “coupling,” establishes some desired electrical communication between two or more circuit nodes, or terminals. Such coupling may often be accomplished using a number of circuit configurations, as will be understood by those of skill in the art. Therefore, the spirit and scope of the appended claims should not be limited to the foregoing description. Only those claims specifically reciting “means for” or “step for” should be construed in the manner required under the sixth paragraph of 35 U.S.C. § 112.

What is claimed is:

1. An integrated-circuit device comprising:
a predriver having a predriver input node and a predriver output node;
a driver having:
a first drive transistor having a control terminal coupled to the predriver output node, a first current-handling terminal coupled to a supply node, and a second current-handling terminal; and
second drive transistors connected in parallel, each second drive transistor having a control terminal, a first current-handling terminal coupled to the second current-handling terminal of the first drive transistor, and a second current-handling terminal;
calibration logic coupled to the control terminals of the second drive transistors, the calibration logic to selectively enable the second drive transistors; and
an output pad coupled second current-handling terminals of the second drive transistors, the output node to provide an external electrical connection from the integrated-circuit device.

2. The integrated-circuit device of claim 1, wherein the predriver consists of an inverting amplifier.

3. The integrated-circuit device of claim 1, wherein each of the first drive transistor and the second drive transistor have a gate of the same gate thickness.

4. The integrated-circuit device of claim 1, wherein the output pad is coupled to the second current-handling terminals of the second drive transistors via a passive resistive element.

5. The integrated-circuit device of claim 4, wherein the passive resistive element consists essentially of a single resistor.

6. The integrated-circuit device of claim 5, wherein the single resistor consists essentially of polysilicon.

7. The integrated-circuit device of claim 1, the predriver further comprising a second predriver input node and a second predriver output node.

8. The integrated-circuit device of claim 7, the driver further comprising:
a third drive transistor having a control terminal coupled to the second predriver output node, a third current-handling terminal coupled to a second supply node, and a fourth current-handling terminal; and
fourth drive transistors connected in parallel, each fourth drive transistor having a control terminal, a first current-handling terminal coupled to the second current-handling terminal of the third drive transistor, and a second current-handling terminal coupled to the output pad.

9. The integrated-circuit device of claim 8, wherein the calibration logic is further coupled to the control terminals of the fourth drive transistors, the calibration logic to selectively enable the fourth drive transistors.

10. The integrated-circuit device of claim 1, further comprising an electrostatic-discharge-protection device coupled between the output pad and the second current-handling terminals of the second drive transistors.

11. A transmitter for transmitting a signal on a transmitter output node, the transmitter comprising:
a first predriver driving a pull-up transistor;
first parallel calibration branches collectively cascode connected to the pull-up transistor;
a first passive resistive element coupled between the first parallel calibration branches and the transmitter output node;
a second predriver driving a pull-down transistor;
second parallel calibration branches collectively cascode connected to the pull-down transistor; and
a second passive resistive element coupled between the second parallel calibration branches and the transmitter output node.

12. The transmitter of claim 11 integrated on and integrated-circuit device, wherein the transmitter output node comprises a pad for external electrical connection to the integrated-circuit device.

13. The transmitter of claim 11, further comprising an electrostatic-discharge-protection device connected to the output node.

14. The transmitter of claim 11, further comprising calibration logic coupled to the first parallel calibration branches and the second parallel calibration branches to selectively disable ones of the first parallel calibration branches and the second parallel calibration branches.

15. The transmitter of claim 11, wherein the passive resistive element comprises a polysilicon resistor.

16. The transmitter of claim 11, wherein at least one of the first predriver and the second predriver consists essentially of an inverter.

17. The transmitter of claim 11, wherein the pull-up transistor comprises a gate dielectric of a dielectric thickness and the first calibration branches comprise second pull-up transistors each having a gate dielectric of the same dielectric thickness.

18. The transmitter of claim 11, wherein the pull-down transistor comprises a gate dielectric of a dielectric thickness and the second calibration branches comprise second pull-down transistors each having a gate dielectric of the same dielectric thickness.

19. The transmitter of claim 11, wherein the pull-up transistor is a PMOS transistor and the pull-down transistor is an NMOS transistor.

20. An amplifier for amplifying a signal between an input node and an output node, the amplifier comprising:
a supply terminal; and
a circuit connected between the supply terminal and the output node, the circuit including, connected in series between the supply terminal and the output node:
a drive transistor having a control terminal coupled to the input node, a first current-handling terminal, and a second current-handling terminal;
a passive resistive element; and
parallel calibration branches collectively connected in the series; and
calibration logic coupled to the parallel calibration branches to selectively disable ones of the branches.

21. The amplifier of claim 19. wherein the passive resistive element is coupled between the calibration branches and the output node.
